(19) United States
(12) Patent Application Publication
(10) Pub. No.: US 2006/0223281 A1
(43) Pub. Date: Oct. 5, 2006

(54) Manufacturing structure

(76) Inventors: Hwa Su, Ping Cheng City (TW); Alexander Chan Wang, Ping Cheng City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/263,914

(22) Filed: Nov. 2, 2005

Related U.S. Application Data
(60) Provisional application No. 60/665,848, filed on Mar. 29, 2005.

(51) Int. Cl. H01L 21/30

(52) U.S. Cl. 438/458

(57) ABSTRACT

This utility discloses a manufacturing structure, suitable for at least one component that accomplishes manufacturing structure with high density and high suppleness. This structure comprises a substrate and at least one hole. These holes are arranged to be an array on the substrate. The size of the hole tallies with the size of the single component that is set into each hole one by one. At the same time, on the substrate, the single component can be a selection unit that selects a distribution area for dividing. By way of mentioned above, the manufacturing structure with high density and high suppleness can be obtained and avoids the waste of the manufacturing cost.

### REFERENCE TO RELATED APPLICATION

This patent application is based on Provisional Patent Application Ser. No. 60/665,848, filed 29 Mar. 2005.

### FIELD OF THE INVENTION

The utility discloses a manufacturing structure that is suitable for at least one component that accomplishes the manufacturing structure with high density and high suppleness.

### BACKGROUND OF THE INVENTION

Light Emitting Diode (LED) in video displays is now in widespread use due to the higher brightness. Traditionally, LED is applied into the lighting market, such as traffic signals, indicators, etc.

Referring to FIG. 1, a block diagram of a conventional single-light-generating-component of a manufacturing structure is illustrated. The single-light-generating-component 11 comprises a substrate 111, a hole 112, eight dies 113, and an electrode 114. The substrate 111 of the single-light-generating-component 11 is a ceramic substrate. Generally speaking; the component of the manufacturing structure in prior art system that digs a bigger hole 112 from the substrate 111 and then embeds eight dies 113 in the hole 112. The die 113 can be a LED. Finally, an electrode mark 114 is marked on the left up side of the substrate 111 in order to mark the electrical interconnection of these dies 113 on the substrate 111. The disadvantage of the manufacturing structure is that the ceramic substrate of the single-light-generating-component 11 is unable to be set more dies 113 that cause the space wasted.

Referring to FIG. 2, a block diagram of a conventional plurality of light generating components of a manufacturing structure is illustrated. The manufacturing structure is to make a plurality of light generating components as the single-light-generating shown in FIG. 1 on a bigger substrate 111. The disadvantage of the manufacturing structure is that the ceramic substrate of the plurality of light generating components 11 is unable to be set more dies 113 that cause space wasted and the distribution of dies 113 is not well distributed that causes the lighting without uniformity.

Referring to FIG. 3, illustrates a block diagram of dividing a plurality of light generating components. The conventional example uses the plurality of light generating components 11 as shown in FIG. 2 for dividing. The dividing can only use eight LED dies 113 to be one unit as a split square 31 shown in FIG. 3. Manufactures are unable to divide the shape according to they desired that can only use the unit with eight dies. The dividing without flexibility causes more expenditure and also causes the lighting without uniformity. Those disadvantages must, be resolved by providing a manufacturing structure with high density and high suppleness.

### SUMMARY OF THE INVENTION

Therefore, the object for the utility is to disclose a manufacturing structure that is suitable for at least one component that accomplishes the manufacturing structure with high density and high suppleness. The manufacturing structure comprises a substrate and at least one hole. These holes are arranged to be an array on the substrate. The size of the hole tallies with the size of the single component that is set into each hole one by one. At the same time, on the substrate, the single component can be a selection unit that selects a distribution area for dividing. By way of mentioned above, the manufacturing structure with high density and high suppleness can be obtained and also avoids the waste of the manufacturing cost. In addition, the substrate in the manufacturing structure can be a ceramic substrate, a glass substrate, or a silicon substrate. The hole in the substrate can be a square hole, a circular hole, or a hole with other shapes. The component is usually a die that can be a LED or Integrated Circuit (IC).

### BRIEF DESCRIPTION OF THE DRAWINGS

FIG. 1 is a block diagram of a conventional single light generating component of a manufacturing structure;

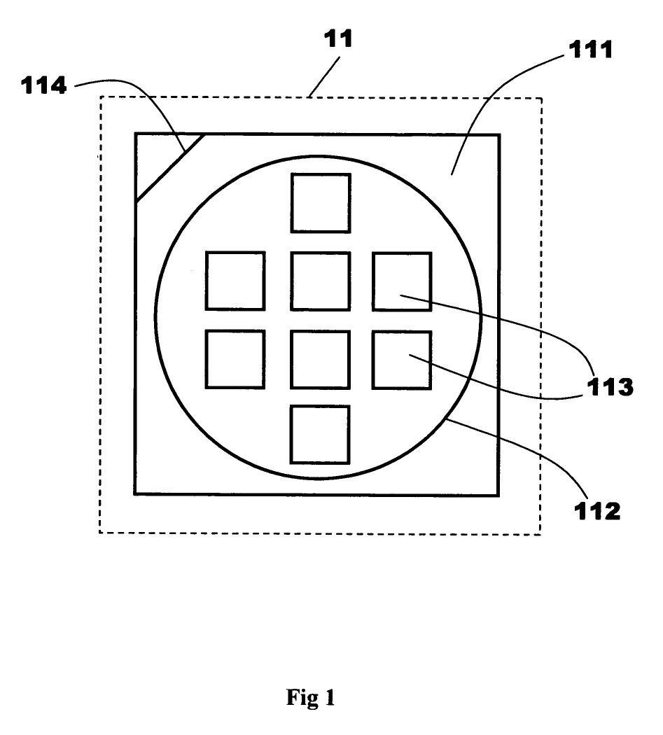

FIG. 2 is a block diagram of a conventional plurality of light generating components of a manufacturing structure;

FIG. 3 is a block diagram of dividing a plurality of light generating components;

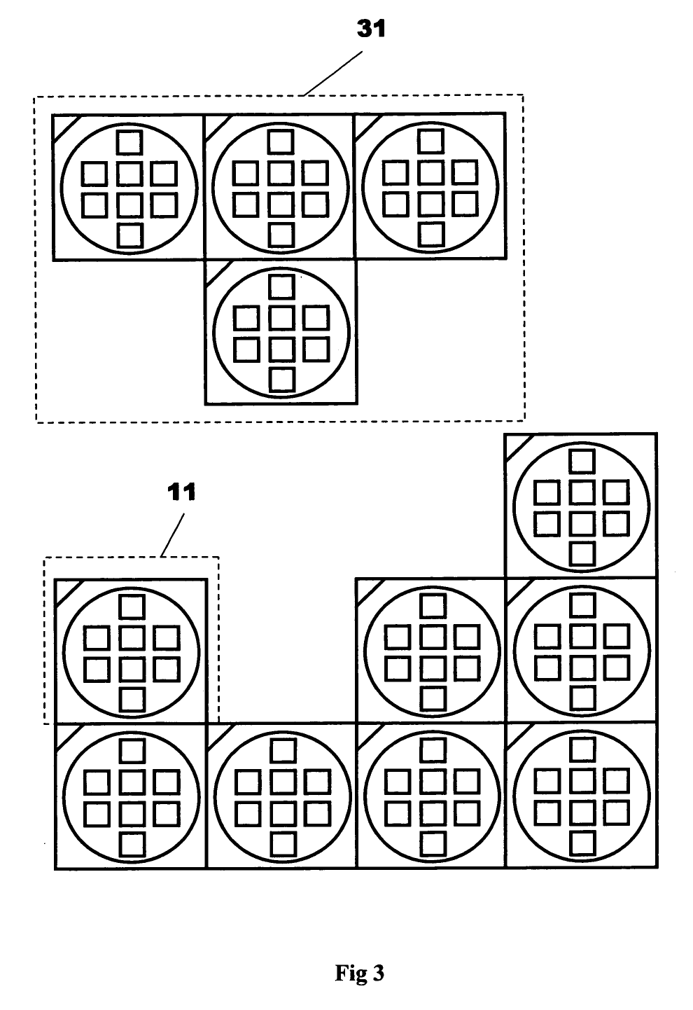

FIG. 4 is a block diagram of an example of a manufacturing structure with high density;

FIG. 5 is a block diagram of an example of using a single die to be a selection unit for dividing components;

FIG. 6 is a block diagram of an example of paralleled sixteen LEDs; and

FIG. 7 is a block diagram of an example of manufacturing sixteen LEDs and an electrode.

### DETAILED DESCRIPTION OF THE PREFERRED EMBODIMENTS

To make it easier for our examiner to understand the objective of the invention, its innovative features and performance, a detailed description and technical characteristics of the present invention are described together with the drawings as follows.

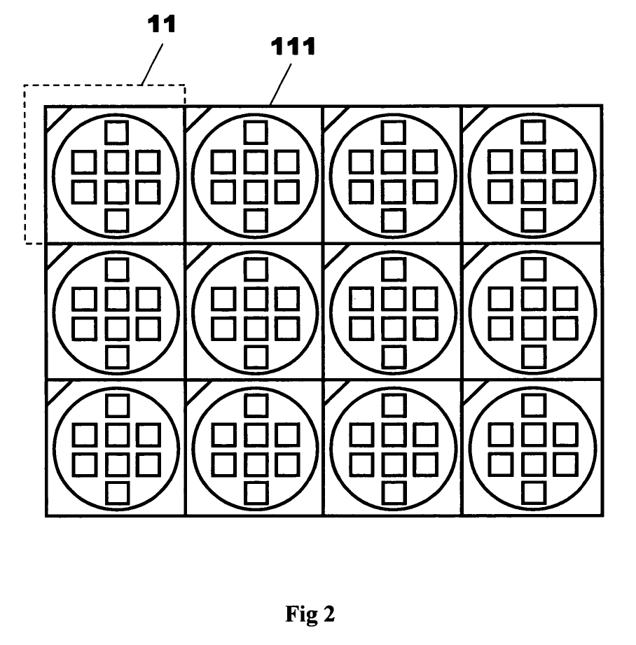

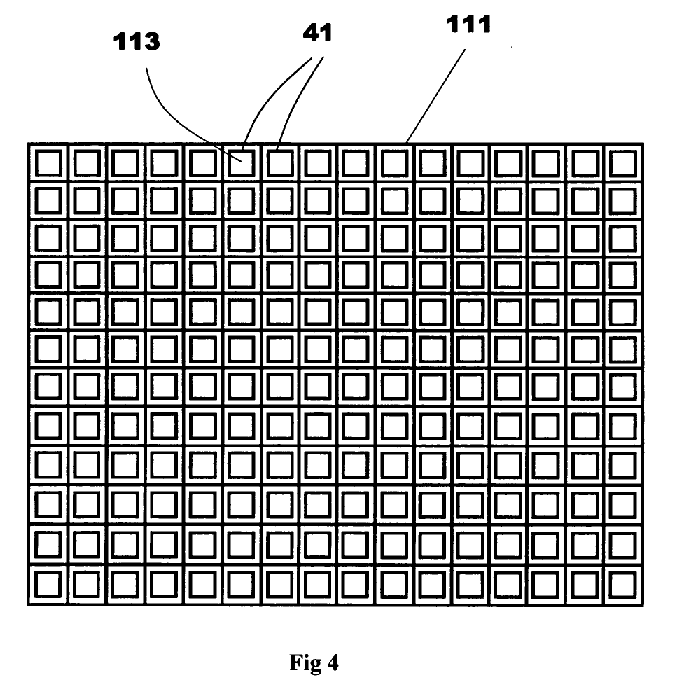

Referring to FIG. 4, a block diagram of an example of a manufacturing structure with high density is illustrated. The manufacturing structure comprises a substrate 111, at least one die 113, and a square hole 41. The size of the square hole 41 obtained from combined advance technologies tallies with the size of the die 113. In addition, the substrate 111 can be a ceramic substrate and the die 113 can be a LED. At the same time, a plurality of square holes 41 can be arranged to be an array in order to obtain a plurality of dies 113 with high density. Referring back to FIG. 2, the conventional example uses eight dies 113 for one unit that can only set ninety-six dies 113, the manufacturing structure in FIG. 4 uses one hundred and ninety two dies 113 that is set on the same size of the substrate 111 that can obtain light generating component with high brightness and high uniformity.

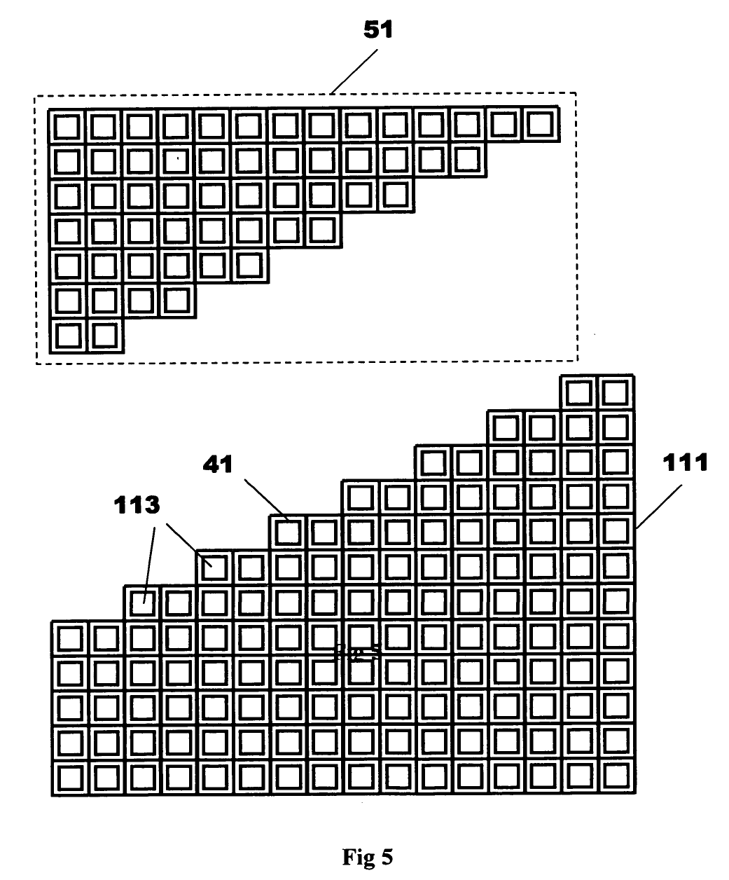

Moreover, referring to FIG. 5, illustrates a block diagram of an example of using a single die to be a selection unit for dividing components. The dividing bases on the component acquired from the manufacturing structure in FIG. 4 that uses a single die 113 to be a unit for dividing according to the desirous of the component shape 51. The dividing with high suppleness can reduce the cost in the component manufacturing to avoid unnecessary wastage in order to keep the outcome with high density, high brightness, and high uniformity.

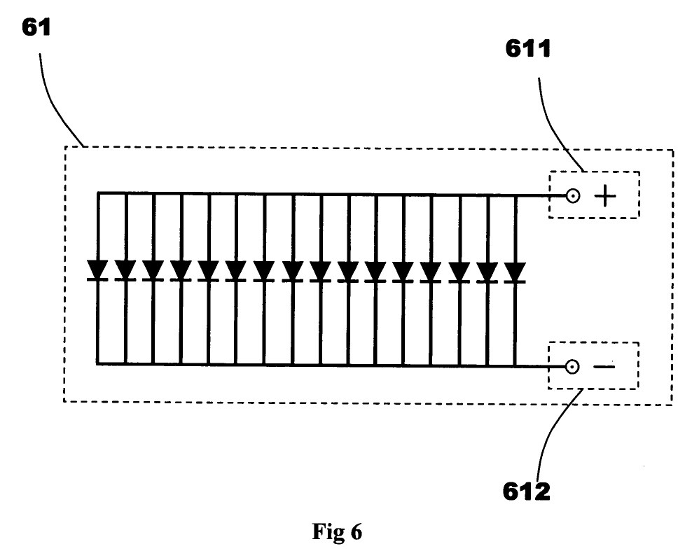

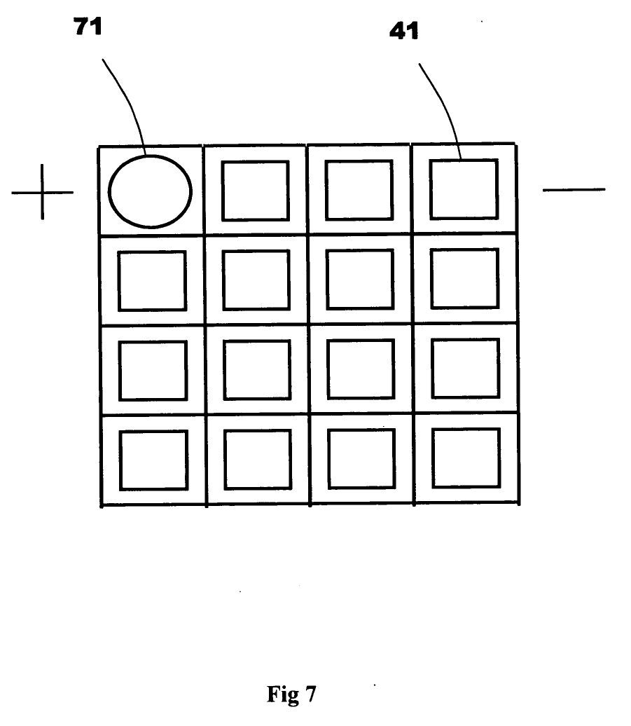

Referring to FIG. 6, illustrates a block diagram of an example of paralleled sixteen LEDs. The paralleled sixteen LEDs 61 have the same an input 611 and an output 612. The paralleled sixteen LEDs 61 are made by the manufacturing structure. Referring to FIG. 7, the circular hole 71 is used to be an electrode of the input 611 that produces recognition to distinguish from others of the plurality of square holes 41. The recognition can be provided for determining the electrode when applying the component.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the description above, the present invention is novel and useful and definite enhances the performance over the conventional structure and further complies with the patent application requirements and is submitted to the Patent and Trademark Office for review and granting of the commensurate patent rights.

What is claimed is:

1. A manufacturing structure, being applied for at least one component, at least comprising:
a substrate; and
at least one hole produced on said substrate and set said component into said hole.

2. The manufacturing structure of claim 1, wherein said hole is arranged to be an array.

3. The manufacturing structure of claim 1, wherein said substrate selects a distribution area for dividing.

4. The manufacturing structure of claim 3, wherein said distribution area is composed of at least one selection unit, said selection unit is a single said component.

5. The manufacturing structure of claim 1, wherein said component is a die.

6. The manufacturing structure of claim 5, wherein said ship is a Light Emitting Diode (LED).

7. The manufacturing structure of claim 1, wherein said substrate is a ceramic substrate.

8. The manufacturing structure of claim 1, wherein said substrate is a glass substrate.

9. The manufacturing structure of claim 1, wherein said substrate is a silicon substrate.

10. The manufacturing structure of claim 1, wherein the size of said hole corresponds to the size of said component.

11. The manufacturing structure of claim 10, wherein said hole is a circular hole.

12. The manufacturing structure of claim 10, wherein said hole is a square hole.
